(19) United States
(12) Patent Application Publication
(10) Pub. No.: US 2022/0302119 A1
(43) Pub. Date: Sep. 22, 2022

(54) DRAM AND FORMATION METHOD THEREOF

(71) Applicant: CHANGXIN MEMORY TECHNOLOGIES, INC., Hefei City (CN)

(72) Inventor: Shuai GUO, Hefei City (CN)

(21) Appl. No.: 17/456,073

(22) Filed: Nov. 22, 2021

Related U.S. Application Data
(63) Continuation of application No. PCT/CN2021/111920, filed on Aug. 11, 2021.

(30) Foreign Application Priority Data
Mar. 17, 2021 (CN) 202110285121.5

(51) Int. Cl. H01L 27/108

(52) U.S. Cl. CPC H01L 27/10805; H01L 27/10891

(57) ABSTRACT

Embodiments of the present application provide a DRAM and a formation method thereof. The DRAM formation method includes providing a semiconductor substrate, a plurality of discrete active regions being formed on the semiconductor substrate; etching the active region to form a wordline trench in the active region; forming a silicon nitride layer on a sidewall and a bottom surface of the wordline trench by a deposition process; completely oxidizing the silicon nitride layer to form a silicon oxide layer on the sidewall and the bottom surface of the wordline trench; and forming a wordline on the silicon oxide layer.

### CROSS-REFERENCE TO RELATED APPLICATIONS

This application is a continuation application of International Patent Application No. PCT/CN2021/111920, filed on Aug. 11, 2021, which is based on and claims priority to Chinese Patent Application No. 202110285121.5, filed on Mar. 17, 2021. The entire contents of International Patent Application No. PCT/CN2021/111920 and Chinese Patent Application No. 202110285121.5 are incorporated herein by reference.

### TECHNICAL FIELD

The present application relates to the field of memories.

### BACKGROUND

A Dynamic Random Access Memory (DRAM) is a semiconductor memory device commonly used in computers, and consists of a plurality of repetitive memory cells. Each memory cell generally includes a capacitor and a transistor. The transistor has a gate connected to a wordline, a drain connected to a bitline and a source connected to the capacitor. A voltage signal on the wordline can control ON and OFF of the transistor so that data information stored in the capacitor can be read through the bitline or data information is written to the capacitor for storage through the bitline.

In order to improve integration of a memory structure, the transistor in the Dynamic Random Access Memory (DRAM) generally has a structure of a trench transistor. The trench transistor has a gate connected to the wordline, a drain region connected to the bitline and a source region connected to the capacitor.

During formation of a gate dielectric layer, a trench transistor of an existing Dynamic Random Access Memory (DRAM) may consume a substrate and the gate dielectric layer has poor quality, which leads to a problem of reduction in a turn-on current.

### SUMMARY

Embodiments of the present application may/at least prevent a problem of reduction in a turn-on current of a trench transistor.

According to some embodiments, in a first aspect, the present application provides a DRAM formation method, including: providing a semiconductor substrate, a plurality of discrete active regions being formed on the semiconductor substrate; etching the active region to form a wordline trench in the active region; forming a silicon nitride layer on a sidewall and a bottom surface of the wordline trench by a deposition process; completely oxidizing the silicon nitride layer to form a silicon oxide layer on the sidewall and the bottom surface of the wordline trench; and forming a wordline on the silicon oxide layer.

According to some embodiments, in a second aspect, the present application provides a DRAM, including: a semiconductor substrate, a plurality of discrete active regions being formed on the semiconductor substrate; a wordline trench located in the active region; a silicon oxide layer located on a sidewall and a bottom surface of the wordline trench, the silicon oxide layer being formed through the following process: forming a silicon nitride layer on the sidewall and the bottom surface of the wordline trench by a deposition process; and completely oxidizing the silicon nitride layer to form the silicon oxide layer on the sidewall and the bottom surface of the wordline trench; and a wordline located on the silicon oxide layer.

### BRIEF DESCRIPTION OF DRAWINGS

In order to more clearly illustrate the technical solutions in the embodiments of the present application or the conventional art, the accompanying drawings used in the description of the embodiments will be briefly introduced below. It is apparent that, the accompanying drawings in the following description are only some embodiments of the present application, and other drawings can be obtained by those of ordinary skill in the art from the provided drawings without creative efforts.

FIG. 1 to FIG. 8 are schematic structural diagrams of a formation process of a memory according to an embodiment of the present application.

### DESCRIPTION OF EMBODIMENTS

As described in the Background, the trench transistor of the existing Dynamic Random Access Memory (DRAM) has the problem of reduction in the turn-on current.

According to a study, in an existing process of forming a structure of a trench transistor, a wordline silicon oxide layer is generally formed on a sidewall and a bottom of a wordline trench in a semiconductor substrate by an Atomic Layer Deposition (ALD) process. The wordline silicon oxide layer formed in this manner has poor quality (specifically, the silicon oxide layer formed has poor density, high defect density, and high roughness). During subsequent In-Situ Steam Generation (ISSG) oxidation (ISSG is performed to uniform a thickness of the oxide layer formed on the sidewall and the bottom of the wordline trench and reduce defects), H₂/O₂ may directly oxidize the semiconductor substrate through the wordline silicon oxide layer formed by deposition (when a line width is further reduced, the substrate may not be sufficient for ISSG oxidation). As a result, sizes of source and drain regions may decrease, and the thickness of the silicon oxide layer formed may increase, so that a turn-on current of the trench transistor decreases at an equal turn-on voltage. In addition, when the wordline silicon oxide layer has poor quality, long-term reliability of a DRAM device is affected, and a service life of the DRAM device is relatively short.

To this end, the present application provides a DRAM and a formation method thereof. The DRAM formation method includes: providing a semiconductor substrate, a plurality of discrete active regions being formed on the semiconductor substrate; etching the active region to form a wordline trench in the active region; forming a silicon nitride layer on a sidewall and a bottom surface of the wordline trench by a deposition process; completely oxidizing the silicon nitride layer to form a silicon oxide layer on the sidewall and the bottom surface of the wordline trench; and forming a wordline on the silicon oxide layer. The silicon nitride layer is formed, and then the silicon nitride layer is completely oxidized to form the silicon oxide layer on the sidewall and the bottom surface of the wordline trench. The silicon oxide layer serves as a wordline silicon oxide layer between a subsequently-formed wordline in the wordline trench and the active region. That is, the formed wordline silicon oxide layer is obtained by completely oxidizing the silicon nitride layer, and silicon in source and drain regions on two sides of the wordline trench may not be consumed, so that a thickness of the formed silicon oxide layer is determined by a thickness of the silicon nitride layer, which ensures stability of the thickness of the silicon oxide layer. Therefore, a turn-on current of a trench transistor may not decrease at an equal turn-on voltage, and sizes of the source and drain regions remain unchanged. Moreover, according to this method, the formed wordline silicon oxide layer may have better quality (specifically, it has higher density, less defect density and a more uniform thickness than the silicon oxide layer formed by the deposition process, and has higher density, higher surface evenness, less surface roughness, and no particle defects on the surface than the silicon oxide layer formed by a silicon oxide material), which can improve the reliability and prolong the service life of the DRAM device. Next, when the silicon nitride layer 212 is oxidized to silicon oxide, there may be some residual N elements, and the residual N elements may form SiON. A dielectric constant of SiON is higher than that of silicon oxide (SiO₂), and isolation performance of the gate dielectric layer can be improved accordingly.

In order to make the above objectives, features and advantages of the present application more obvious and understandable, specific implementations of the present application are described in detail below with reference to the accompanying drawings. When the embodiments of the present application are described in detail, for ease of description, the schematic diagrams may not be partially enlarged to normal proportions, and the schematic diagrams are examples only, which should not limit the protection scope of the present application herein. In addition, three-dimensional dimensions of length, width and depth should be included in actual manufacturing.

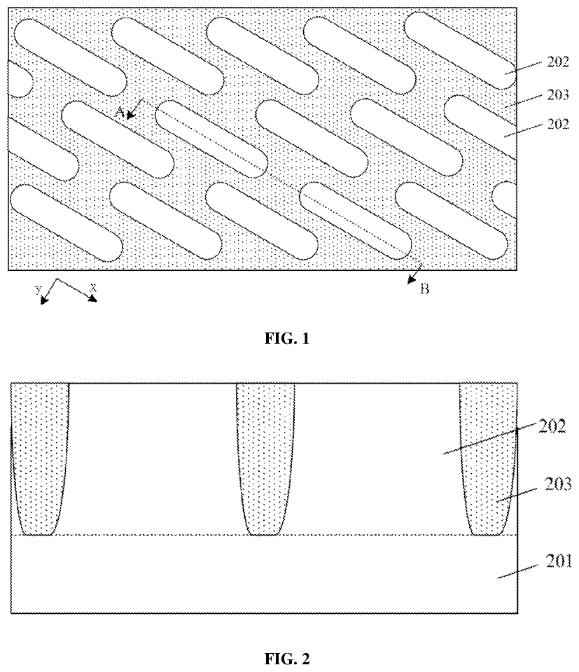

Referring to FIG. 1 to FIG. 2, FIG. 2 is a schematic diagram of a sectional structure along a direction AB of a cutting line in FIG. 1. A semiconductor substrate 201 is provided. A plurality of discrete active regions 202 are formed on the semiconductor substrate 201.

The semiconductor substrate 201 may be made of silicon (Si), germanium (Ge), silicon germanium (GeSi), or silicon carbide (SiC); or silicon on insulator (SOI), germanium on insulator (GOI); or other materials, such as gallium arsenide and other compounds. In this embodiment, the semiconductor substrate 201 is made of silicon. The semiconductor substrate is doped with certain impurity ions as needed. The impurity ions may be N-type impurity ions or P-type impurity ions. In one embodiment, the doping includes well region doping and source and drain region doping.

The plurality of active regions 202 are isolated by an isolation layer 203.

In one embodiment, a formation process of the active region 202 and the isolation layer 203 involves: forming a first mask layer (not shown in the drawings) on the semiconductor substrate 201, the first mask layer having a plurality of first mask openings distributed in parallel; etching, by using the first mask layer as a mask, the semiconductor substrate 201 along the first mask opening to form a plurality of discrete Strip initial active regions in the semiconductor substrate 201, a first trench being provided between the adjacent Strip initial active regions; etching the Strip initial active region to form a plurality of second trenches in the Strip initial active region, the second trench dividing each Strip initial active region into a plurality of active regions 202; and filling the first trench and the second trench with an isolation material to form the isolation layer 203. The isolation layer 203 may be made of silicon oxide or other suitable isolation materials (in other embodiments, firstly, the first trench is filled with the isolation material to form a first isolation layer, and after the first isolation layer is formed, the Strip initial active region is etched to form a plurality of second trenches in the Strip initial active region; then, the second trench is filled with the isolation material to form a second isolation layer; the first isolation layer and the second isolation layer constitute the isolation layer). It is to be noted that, to facilitate the distinction between the active region 202 and the semiconductor substrate 201, the active region 202 and the semiconductor substrate 201 are separated by a dashed line in FIG. 2.

In other embodiments, the active region 202 may be formed by an epitaxy process.

In the present embodiment, an x-axis direction shown in FIG. 1 is used as a row direction, and a y-axis direction is used as a column direction. Positions of the active regions 202 in adjacent rows may be misaligned to some extent.

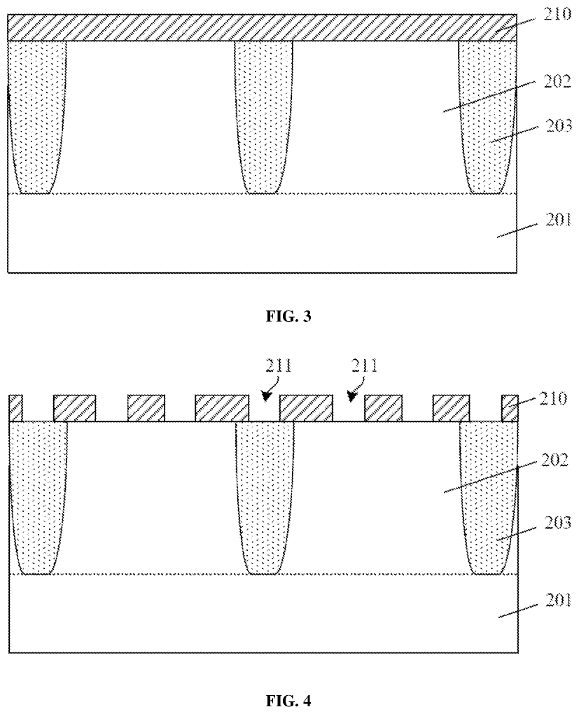

Referring to FIG. 3, a mask layer 210 is formed on the active region 202 and the isolation layer 203.

The mask layer 210 may be made of one or more of silicon oxide, silicon nitride and silicon oxynitride. The mask layer 210 may be of a monolayer or multilayer stack structure.

In one embodiment, the mask layer 210 includes a silicon nitride layer and an amorphous carbon layer located on the silicon nitride layer. The silicon nitride layer and the amorphous carbon layer are formed by a chemical vapor deposition process.

Referring to FIG. 4, a plurality of parallel openings 211 are formed in the mask layer 210.

In one embodiment, an extension direction of the opening 211 forms an angle relative to an extension direction of the active region 202. Each of the openings 211 exposes part of a surface of the active region 202 and part of a surface of the isolation layer 203 on two sides of the active region 202.

The mask layer 210 is patterned to form the opening 211 in the mask layer 210. Specifically, firstly, a photoresist layer (not shown in the drawings) is formed on the mask layer 210; exposing and developing the photoresist layer, and patterning the photoresist layer; and then, the mask layer 210 is etched, by using the patterned photoresist layer as a mask, to form the opening 211 in the mask layer 210.

In one embodiment, the mask layer 210 is etched by an anisotropic plasma etching process.

The mask layer 210 is used as a mask to subsequently etch the active region 202 and the isolation layer 203 to form the wordline trench. In one embodiment, two openings 211 are correspondingly formed in the mask layer 210 on each active region 202. Two wordline trenches are subsequently formed correspondingly in each active region 202 by etching.

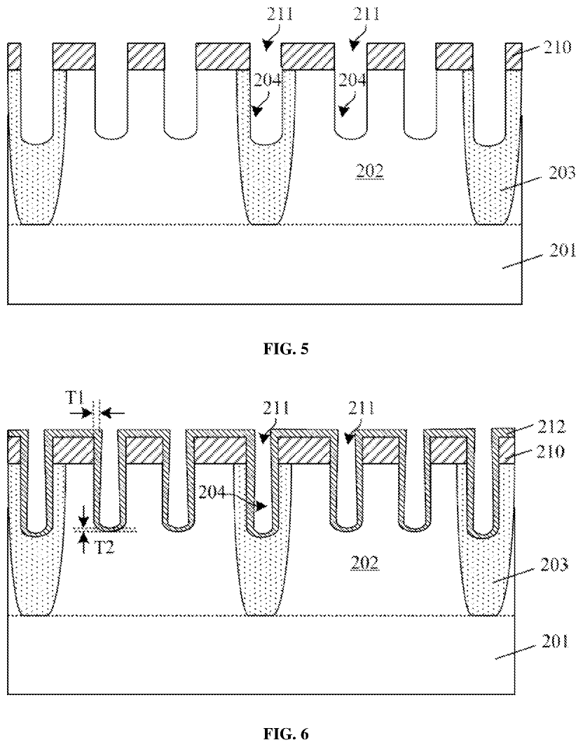

Referring to FIG. 5, part of the active region 202 and the isolation layer 203 are etched away, by using the mask layer 210 as a mask, to form a wordline trench 204 in the active region 202 and the isolation layer 203.

The wordline trench 204 includes a first-part wordline trench located in the active region 202 and a second-part wordline trench located in the isolation layer. In fact, one wordline trench includes a first-part wordline trench and a second-part wordline trench.

In one embodiment, when two openings 211 are correspondingly formed in the mask layer 210 on each active region 202, two wordline trenches 204 are correspondingly formed in each active region 202, so as to facilitate subsequent formation of a double-trench transistor. Specifically, the two wordline trenches 204 divide each active region 202 into a drain region located in a middle and two source regions located on two sides of the drain region respectively.

Part of the active region 202 and the isolation layer 203 may be etched away by an anisotropic plasma etching process. In one embodiment, an etching gas used in the anisotropic plasma etching process includes one or any combination of Cl₂, HBr, CF₄ and CHF₃. In one embodiment, the etching gas used in steps of the anisotropic plasma etching process further includes one or a combination of helium and argon.

Referring to FIG. 6, a silicon nitride layer 212 is formed on a sidewall and a bottom surface of the wordline trench 204 by a deposition process.

The silicon nitride layer 212 is formed, and then the silicon nitride layer 212 is completely oxidized to form the silicon oxide layer on the sidewall and the bottom surface of the wordline trench 204. The silicon oxide layer serves as a wordline silicon oxide layer between a subsequently-formed wordline in the wordline trench and the active region 202. That is, the formed wordline silicon oxide layer is obtained by completely oxidizing the silicon nitride layer 212 in the method, and silicon in source and drain regions on two sides of the wordline trench 204 may not be consumed, so that a thickness of the formed silicon oxide layer is determined by a thickness of the silicon nitride layer 212, which ensures stability of the thickness of the silicon oxide layer. Therefore, a turn-on current of a trench transistor may not decrease at an equal turn-on voltage, and sizes of the source and drain regions can remain unchanged. Moreover, according to this method, the formed wordline silicon oxide layer may have better quality (specifically, it has higher density, less defect density and a more uniform thickness than the silicon oxide layer formed by the deposition process, and has higher density, higher surface evenness, less surface roughness, and no particle defects on the surface than the silicon oxide layer formed by a silicon oxide material), which can improve the reliability and prolong the service life of the DRAM device. Next, when the silicon nitride layer 212 is oxidized to silicon oxide, there may be some residual N elements, and the residual N elements may form SiON. A dielectric constant of SiON is higher than that of silicon oxide (SiO₂), and isolation performance of the gate dielectric layer can be improved accordingly.

The deposition process for forming the silicon nitride layer 212 is an atomic layer deposition process.

In one embodiment, a thickness T1 of the silicon nitride layer 212 on the sidewall surface of the wordline trench 204 is greater than a thickness T2 of the silicon nitride layer 212 at the bottom of the wordline trench 204. When the silicon nitride layer 212 is subsequently completely oxidized to form the silicon oxide layer on the sidewall and the bottom surface of the wordline trench 204, the thickness of the silicon oxide layer formed on the sidewall surface of the wordline trench 204 is correspondingly greater than the thickness of the silicon oxide layer formed at the bottom of the wordline trench 204. Therefore, when the trench transistor operates, an electric field near the source region and the drain region may be lower, while an electric field near a channel region may be higher, resulting in an electric field difference and reducing gate-induced drain leakage (GIDL), so as to further prevent the reduction in the turn-on current, so that the performance of the trench transistor is further improved, thereby further improving the performance of the DRAM.

In one embodiment, the thickness of the silicon nitride layer 212 on the sidewall surface of the wordline trench 204 gradually decreases from top to bottom.

In one embodiment, a ratio of the thickness of the silicon nitride layer 212 on the sidewall surface of the wordline trench 204 to the thickness of the silicon nitride layer 212 at the bottom of the wordline trench 204 is 2:1 to 4:3. According to a study, the silicon nitride layer 212 should not be too thick or too thin, as a too thick silicon nitride layer may lead to incomplete oxidation, and a too thin silicon nitride layer cannot meet electrical requirements. Specifically, the thickness of the silicon nitride layer 212 on the sidewall surface of the wordline trench 204 is 8 nm to 10 nm, and the thickness of the silicon nitride layer 212 at the bottom of the wordline trench 204 is 5 nm to 7 nm.

In order to form the silicon nitride layer 212 of the foregoing particular structure (the thickness T1 of the silicon nitride layer 212 on the sidewall surface of the wordline trench 204 is greater than the thickness T2 of the silicon nitride layer 212 at the bottom of the wordline trench 204), the atomic layer deposition process involves a silicon source gas and a nitrogen source gas, the silicon source gas includes dichlorosilane (DCS), the nitrogen source gas includes NH₃, a flow rate of the silicon source gas ranges from 200 sccm to 600 sccm, specifically, 350 sccm to 480 sccm, a flow rate of the nitrogen source gas ranges from 2000 sccm to 15000 sccm, and a reaction by-product is extracted from a deposition chamber by using a pump of 5000 L/min Under a condition of the foregoing particular atomic layer deposition process, the gas flows from top to bottom under a low pressure and a small flow rate of a source gas supplied for thin film deposition, and a pressure of an upper part of the wordline trench 204 is greater than a pressure of a lower part. Therefore, the thickness T1 of the silicon nitride layer 212 formed on the sidewall surface of the wordline trench 204 may be easily greater than the thickness T2 of the silicon nitride layer 212 formed at the bottom of the wordline trench 204.

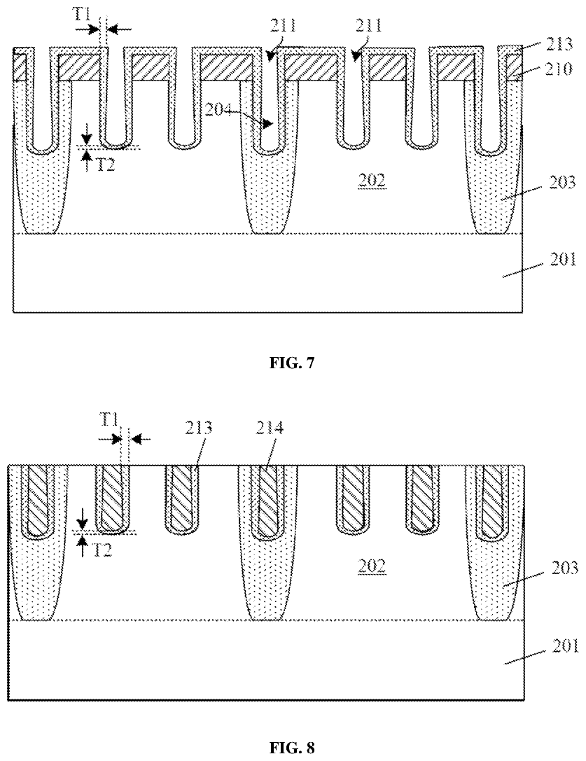

Referring to FIG. 7, the silicon nitride layer 212 (refer to FIG. 6) is completely oxidized to form a silicon oxide layer 213 on the sidewall and the bottom surface of the wordline trench 204.

The silicon nitride layer 212 is completely oxidized to the silicon oxide layer 213 by in-situ steam generation (ISSG) oxidation or a rapid thermal oxidation process.

In one embodiment, a thickness T1 of the silicon oxide layer 213 on the sidewall surface of the wordline trench 204 is greater than a thickness T2 of the silicon oxide layer 213 at the bottom of the wordline trench 204. After the wordline is subsequently formed on the surface of the silicon oxide layer 213, when the trench transistor operates, an electric field near the source region and the drain region may be lower, while an electric field near a channel region may be higher, resulting in an electric field difference and reducing gate-induced drain leakage (GIDL), so as to further prevent the reduction in the turn-on current, so that the performance of the trench transistor is further improved, thereby further improving the performance of the DRAM.

In one embodiment, the thickness of the silicon oxide layer 213 on the sidewall surface of the wordline trench 204 gradually decreases from top to bottom.

In one embodiment, a ratio of the thickness T1 of the silicon oxide layer 213 on the sidewall surface of the wordline trench 204 to the thickness of the silicon oxide layer 213 at the bottom of the wordline trench 204 is 2:1 to 4:3. Specifically, the thickness of the silicon oxide layer on the sidewall surface of the wordline trench is 8 nm to 10 nm, and the thickness of the silicon oxide layer at the bottom of the wordline trench is 5 nm to 7 nm.

In one embodiment, the silicon nitride layer 212 is completely oxidized to the silicon oxide layer 213 by an in-situ steam generation (ISSG) oxidation process. Oxygen and hydrogen are introduced into a reaction chamber in the in-situ steam generation oxidation process, a flow rate of oxygen is more than 10 times that of hydrogen, the reaction chamber is at a temperature of 900° C. to 1300° C., and the reaction chamber is at a pressure of 4 torr to 15 torr. Oxygen and hydrogen are introduced in a certain proportion at a low pressure. The reason why the oxygen ratio is higher than the hydrogen ratio is to form a steam environment and to provide an enough oxygen source for the formation of silicon oxide. An oxidation layer can be grown faster in an atmosphere of high-temperature steam, and a gate oxide film grown by in-situ water vapor generation has better density.

Referring to FIG. 8, a wordline 214 is formed on the silicon oxide layer 213.

The wordline 214 may be made of W or other suitable metal materials.

In one embodiment, a formation process of the wordline 214 involves: forming a metal layer on the silicon oxide layer 213, the wordline trench being filled up with the metal layer; and removing, by planarization, the metal layer from the surface of the semiconductor substrate to form the wordline 214.

In a specific embodiment, the wordline 214 may be flush with a surface of the active region 202, or below the surface of the active region 202, or slightly above the surface of the active region 202.

Another embodiment of the present application further provides a DRAM, referring to FIG. 8, including:

a semiconductor substrate 201, a plurality of discrete active regions 202 being formed on the semiconductor substrate 201;

a wordline trench located in the active region 202;

a silicon oxide layer 213 located on a sidewall and a bottom surface of the wordline trench, the silicon oxide layer 213 being formed through the following process: forming a silicon nitride layer on the sidewall and the bottom surface of the wordline trench by a deposition process; and completely oxidizing the silicon nitride layer to form the silicon oxide layer on the sidewall and the bottom surface of the wordline trench; and

a wordline 214 located on the silicon oxide layer 213.

In one embodiment, a thickness T1 of the silicon oxide layer 213 on a sidewall surface of the wordline trench is greater than a thickness T2 of the silicon oxide layer 213 at a bottom of the wordline trench.

In one embodiment, the thickness of the silicon oxide layer 213 on the sidewall surface of the wordline trench gradually decreases from top to bottom.

In one embodiment, a ratio of the thickness T1 of the silicon oxide layer 213 on the sidewall surface of the wordline trench to the thickness T2 of the silicon oxide layer 213 at the bottom of the wordline trench is 2:1 to 4:3. Specifically, the thickness T1 of the silicon oxide layer 213 on the sidewall surface of the wordline trench is 8 nm to 10 nm, and the thickness T2 of the silicon oxide layer 213 at the bottom of the wordline trench is 5 nm to 7 nm.

The plurality of active regions 202 are isolated by an isolation layer 203.

In one embodiment, each active region 202 has two wordline trenches. Correspondingly, each active region 202 has two wordlines 214.

It is to be noted that, other limitations or descriptions of the memory (DRAM) in the present embodiment are not described in detail in the present embodiment. Refer to the corresponding limitations or descriptions in the embodiment of the formation process of the memory (DRAM) for details.

Although the present application has been disclosed as above with preferred embodiments, the present application should not be limited by those embodiments. Any person skilled in the art may make possible changes and modifications to the present application based on the methods and technical contents disclosed above without departing from the spirit and scope of the present application. Therefore, any simple alterations, equivalent changes and modifications made to the foregoing embodiments based on the technical essence of the present application without departing from the technical solutions of the present application are deemed to fall within the protection scope of the technical solutions in the present application.

What is claimed is:

1. A Dynamic Random Access Memory (DRAM) formation method, comprising:
providing a semiconductor substrate, a plurality of discrete active regions being formed on the semiconductor substrate;
etching the active region to form a wordline trench in the active region;
forming a silicon nitride layer on a sidewall and a bottom surface of the wordline trench by a deposition process;
completely oxidizing the silicon nitride layer to form a silicon oxide layer on the sidewall and the bottom surface of the wordline trench; and
forming a wordline on the silicon oxide layer.

2. The DRAM formation method according to claim 1, wherein the silicon nitride layer is completely oxidized to the silicon oxide layer by an in-situ steam generation oxidation process or a rapid thermal oxidation process.

3. The DRAM formation method according to claim 1, wherein a thickness of the silicon oxide layer on a sidewall surface of the wordline trench is greater than a thickness of the silicon oxide layer at a bottom of the wordline trench.

4. The DRAM formation method according to claim 3, wherein the thickness of the silicon oxide layer on the sidewall surface of the wordline trench gradually decreases from top to bottom.

5. The DRAM formation method according to claim 3, wherein a ratio of the thickness of the silicon oxide layer on the sidewall surface of the wordline trench to the thickness of the silicon oxide layer at the bottom of the wordline trench is 2:1 to 4:3.

6. The DRAM formation method according to claim 3, wherein the thickness of the silicon oxide layer on the sidewall surface of the wordline trench is 8 nm to 10 nm, and the thickness of the silicon oxide layer at the bottom of the wordline trench is 5 nm to 7 nm.

7. The DRAM formation method according to claim 3, wherein a formation process of the silicon oxide layer involves: forming the silicon nitride layer on the sidewall and the bottom surface of the wordline trench by an atomic layer deposition process, a thickness of the silicon nitride layer on the sidewall surface of the wordline trench being greater than a thickness of the silicon nitride layer at the bottom of the wordline trench; and completely oxidizing the silicon nitride layer to the silicon oxide layer by an in-situ steam generation oxidation process, and forming the silicon oxide layer on the sidewall and the bottom surface of the wordline trench, the thickness of the silicon oxide layer on the sidewall surface of the wordline trench being greater than the thickness of the silicon oxide layer at the bottom of the wordline trench.

8. The DRAM formation method according to claim 7, wherein the thickness of the silicon nitride layer on the sidewall surface of the wordline trench gradually decreases from top to bottom.

9. The DRAM formation method according to claim 7, wherein the atomic layer deposition process involves a silicon source gas and a nitrogen source gas, the silicon source gas comprises dichlorosilane (DCS), the nitrogen source gas comprises NH₃, a flow rate of the silicon source gas ranges from 200 sccm to 600 sccm, a flow rate of the nitrogen source gas ranges from 2000 sccm to 15000 sccm, and a reaction by-product is extracted from a deposition chamber by using a pump of 5000 L/min.

10. The DRAM formation method according to claim 6, wherein oxygen and hydrogen are introduced into a reaction chamber in an in-situ steam generation oxidation process, a flow rate of oxygen is more than 10 times that of hydrogen, the reaction chamber is at a temperature of 900° C. to 1300° C., and the reaction chamber is at a pressure of 4 torr to 15 torr.

11. The DRAM formation method according to claim 1, wherein the active regions are isolated by an isolation layer.

12. The DRAM formation method according to claim 1, wherein each active region has two wordline trenches.

13. A Dynamic Random Access Memory (DRAM), comprising:
a semiconductor substrate, a plurality of discrete active regions being formed on the semiconductor substrate;
a wordline trench located in the active region;
a silicon oxide layer located on a sidewall and a bottom surface of the wordline trench, the silicon oxide layer being formed through the following process: forming a silicon nitride layer on the sidewall and the bottom surface of the wordline trench by a deposition process; and
completely oxidizing the silicon nitride layer to form the silicon oxide layer on the sidewall and the bottom surface of the wordline trench; and
a wordline located on the silicon oxide layer.

14. The DRAM according to claim 13, wherein a thickness of the silicon oxide layer on a sidewall surface of the wordline trench is greater than a thickness of the silicon oxide layer at a bottom of the wordline trench.

15. The DRAM according to claim 14, wherein the thickness of the silicon oxide layer on the sidewall surface of the wordline trench gradually decreases from top to bottom.

16. The DRAM according to claim 14, wherein a ratio of the thickness of the silicon oxide layer on the sidewall surface of the wordline trench to the thickness of the silicon oxide layer at the bottom of the wordline trench is 2:1 to 4:3.

17. The DRAM according to claim 16, wherein the thickness of the silicon oxide layer on the sidewall surface of the wordline trench is 8 nm to 10 nm, and the thickness of the silicon oxide layer at the bottom of the wordline trench is 5 nm to 7 nm.
